(19) United States
(12) Patent Application Publication
(10) Pub. No.: US 2026/0164536 A1
(43) Pub. Date: Jun. 11, 2026

(54) NON-PLANAR ARRANGEMENT OF POWER CHIPS FOR THERMAL MANAGEMENT

(71) Applicant: Atieva, Inc., Newark, CA (US)

(72) Inventors: Bai Shao, Fremont, CA (US); Eric Magnus Bach, Los Altos Hills, CA (US); James Hawkins, Fremont, CA (US); Shun-Cheng Hung, Taipei City (TW); Cheng-Hung Lee, Taipei City (TW); Yung-Chuan Chien, New Taipei City (TW); Mingkai Mu, Fremont, CA (US)

(21) Appl. No.: 18/704,257

(22) PCT Filed: Oct. 25, 2022
(86) PCT No.: PCT/US2022/078657

§ 371 Date: Apr. 24, 2024

Related U.S. Application Data
(60) Provisional application No. 63/263,093, filed on Oct. 27, 2021.

(51) Int. Cl. H05K 1/02; H05K 1/181; H05K 7/20

(52) U.S. Cl. CPC H05K 1/0204; H05K 1/0272; H05K 1/181; H05K 7/20927

(57) ABSTRACT

A device may include a plurality of power chips arranged in a first row in a first plane and being electrically coupled to a printed circuit board, the first plane being non-parallel to a plane of the printed circuit board. A device may include a plurality of power chips arranged in a second row in a second plane and being electrically coupled to the printed circuit board, the second plane being non-parallel to the plane of the printed circuit board and non-parallel to the first plane.

### CROSS-REFERENCE TO RELATED APPLICATION

This application claims priority to U.S. Provisional Patent Application No. 63/263,093, filed on Oct. 27, 2021, and entitled “NON-PLANAR ARRANGEMENT OF POWER CHIPS FOR THERMAL MANAGEMENT,” the disclosure of which is incorporated by reference herein in its entirety.

### TECHNICAL FIELD

This disclosure relates to electrical power chips on a printed circuit board and, in particular, a non-planar arrangement of power chips for thermal management of the power chips.

### BACKGROUND

In recent years, the world's transportation has begun a transition away from powertrains primarily driven by fossil fuels and toward more sustainable energy sources, chiefly among them electric motors powered by on-board energy storages. In order to make these new modes of transportation available to larger segments of population, vehicle makers are striving to reduce the cost of manufacturing, including the cost of assembling battery packs to power electric motors.

### SUMMARY

In some aspects, an apparatus includes a plurality of power chips arranged in a first row in a first plane and being electrically coupled to a printed circuit board, the first plane being non-parallel to a plane of the printed circuit board; and a plurality of power chips arranged in a second row in a second plane and being electrically coupled to the printed circuit board, the second plane being non-parallel to the plane of the printed circuit board and non-parallel to the first plane.

Implementations can include one or more of the following features, alone or in any combination with each other.

For example, the first plane can oriented at a 90 degree angle to the second plane.

For example, the first plane and the second plane can each be oriented at 45 degree angles to the plane of the printed circuit board.

For example, the apparatus can further include a chip holder assembly that includes a first row of a first plurality of receptacles configured for receiving the power chips arranged in the first row and second plurality of receptacles configured for receiving the power chips arranged in the second row, the chip holder assembly including a central beam member that connects the first plurality of receptacles to the second plurality of receptacles.

For example, the central beam member can be arranged in a plane parallel to the printed circuit board and can include a plurality of through holes configured for receiving a fastener for securing the chip holder assembly to the printed circuit board.

For example, the chip holder assembly can include high-thermal-conductivity, electrically insulating ceramic material and where the receptacles are configured for electrically isolating the power chips from each other.

For example, the apparatus can further include a plurality of heat sinks mechanically coupled to the power chips in the first and second rows and configured to extract and dissipate heat from the power chips.

For example, the apparatus can further include a cooling channel in thermal contact with the power chips arranged in the first row and with the power chips arranged in the second row.

For example, the apparatus can further include a plurality of springs configured to press the power chips into thermal contact with the cooling channel.

For example, the apparatus can further include a chip holder assembly that includes a first row of a first plurality of receptacles configured for receiving the power chips arranged in the first row and second plurality of receptacles configured for receiving the power chips arranged in the second row, the chip holder assembly including a central beam member that connects the first plurality of receptacles to the second plurality of receptacles; and a compression beam that is mechanically secured against the central beam member, which, in turn, presses mechanical springs located between the compression beam and the power chips against surfaces of an enclosure surrounding the power chips.

For example, the cooling channel can include metal walls defining an interior cavity, the apparatus further including a plurality of ceramic thermal conductors, the ceramic conductors located between the power chips and a metal wall of the cooling channel and being in thermal contact with the power chip and the metal wall.

For example, the apparatus can further include thermal grease between the ceramic conductors and the power chips.

For example, the cooling channel can include an inlet configured for injecting coolant liquid into the channel and an outlet configured for the coolant liquid to exit the channel.

For example, the power chips can be located between the cooling channel and the printed circuit board.

For example, each power chip can include a power SiC MOSFET transistor.

For example, the power chips can be configured to switch electrical power to a battery of an electric vehicle.

### BRIEF DESCRIPTION OF DRAWINGS

FIG. 1 is a schematic perspective view of an example vehicle.

FIG. 2 is a schematic perspective view of a printed circuit board (PCB) for use in an onboard charger, where a number of electrical components are attached to the PCB.

FIG. 3 is a schematic perspective view of four example power chips, each of which can include one or more electrical connectors (e.g., metal legs) that can be electrically connected to a printed circuit board.

FIG. 4 is an exploded view of a first row and second row of power chips, a row of mechanical springs configured to mechanically maintain the power chips in a desired location, and a printed circuit board to which the power chips and the row of springs are fastened when the printed circuit board is used in an onboard charger.

FIG. 5 is a schematic perspective view of one portion of an enclosure in which rows of power chips can be mounted for use in an onboard charger.

FIG. 6 is a schematic perspective view of a plurality of power chips in a plurality of chip holder assemblies that are coupled to first and second surfaces of an enclosure.

FIG. 7 is a schematic side view of power chips in an assembled position within an enclosure.

FIG. 8 is a schematic diagram of an enclosure after the power chips have been assembled in their respective plurality of rows that are in different planes.

### DETAILED DESCRIPTION

This document describes examples of systems and techniques for arranging multiple electrical power chips in an enclosure. For example, the power chips can be part of an electrical power system of an electric vehicle and can be used to provide electrical power to systems of the vehicle. The electrical power chips can be components of an onboard charger of the electric vehicle, where the onboard charger (OBC) receives electrical power from outside the vehicle and converts the received electrical power into a from that can be store in energy storage systems (e.g., batteries) of the vehicle.

In some implementations, the OBC can receive alternating current (AC) electrical power, convert the AC signal to direct current (DC), set a voltage of the DC electrical power, and provide the DC electrical power to the energy storage systems. The OBC can control the DC electrical power that is provided to the energy storage systems, such that the DC power is provided at a constant voltage or such that the power is provided at a constant current. In some implementations, a charging strategy may entail changing from providing DC power at constant voltage and at constant current as the battery is charged to optimize charging speed and battery life. The OBC uses a number of power chips (e.g., silicon carbide (SiC) MOSFETs) to perform its functions, and the power chips dissipate heat during their operation.

This document describes examples of systems and techniques for manufacturing a OBC that can be used in an electric vehicle to distribute electrical power from a charging source to one or more battery modules of the vehicle and to distribute electrical power from the one or more battery modules to components of the vehicle that use electrical power for their operation. The OBC can include a plurality of power chips (e.g., transistors) that are used to switch electrical power within the OBC and that produce heat during their operation. To provide a compact arrangement of the power chips in the OBC, the power chips can be arranged in two more planes that are not parallel to each other. For example, the first row of the power chips can be arranged in a first plane, and a second row of power chips can be arranged in a second plane, where the second plane is not parallel to the first plane. For example, the second plane can be oriented at a 90° angle to the first plane. By arranging the power chips in multiple different planes that are not parallel to each other, the footprint of a printed circuit board of the OBC can be smaller than if the power chips were all arranged in the same plane.

To dissipate heat from the power chips, the power chips can be thermally coupled to one or more cooling channels through which heat is removed from the power chips during their operation. An arrangement is described in which a plurality of rows of power chips, where the rows are arranged in different planes, are easily assembled in a configuration that couples the power chips to the cooling channels during assembly of the OBC.

Examples herein refer to a battery module, which is an individual component configured for holding and managing multiple electrochemical cells during charging, storage, and use. The battery module can be intended as the sole power source for one or more loads (e.g., electric motors), or more than one battery module of the same or different type can be used. Two or more battery modules can be implemented in a system separately or as part of a larger energy storage unit. For example, a battery pack can include two or more battery modules of the same or different type. A battery module can include control circuitry for managing the charging, storage, and/or use of electrical energy in the electrochemical cells, or the battery module can be controlled by an external component. For example, a battery management system can be implemented on one or more circuit boards (e.g., a printed circuit board). In some implementations, a battery module can be connected to an onboard charger (OBC) that includes control circuitry for managing the charging, storage, and/or use of electrical energy in the electrochemical cells, or the battery module can be controlled by an external component. For example, a battery management system can be implemented on one or more circuit boards (e.g., a printed circuit board) in the OBC.

Examples herein refer to electrochemical cells. An electrochemical cell can include an electrolyte and two electrodes to store energy and deliver it when used. In some implementations, the electrochemical cell can be a rechargeable cell. For example, the electrochemical cell can be a lithium-ion cell. In some implementations, the electrochemical cell can act as a galvanic cell when being discharged, and as an electrolytic cell when being charged. The electrochemical cell can have at least one terminal for each of the electrodes. The terminals, or at least a portion thereof, can be positioned at one end of the electrolytic cell. For example, when the electrochemical cell has a cylindrical shape, one of the terminals can be provided in the center of the end of the cell, and the can that forms the cylinder can constitute the other terminal and therefore be present at the end as well. Other shapes of electrochemical cells can be used, including, but not limited to, prismatic shapes.

Examples described herein refer to a vehicle. As used herein, a vehicle is a machine that transports passengers or cargo, or both. A vehicle can have one or more motors using at least one type of fuel or other energy source (e.g., electricity). Examples of vehicles include, but are not limited to, cars, trucks, and buses. The number of wheels can differ between types of vehicles, and one or more (e.g., all) of the wheels can be used for propulsion of the vehicle. The vehicle can include a passenger compartment accommodating one or more persons. A vehicle can be powered by one or more types of power sources. In some implementations, a vehicle is powered solely by electricity, or can use one or more other energy sources in addition to electricity, to name just a few examples.

As used herein, the terms “electric vehicle” and “EV” may be used interchangeably and may refer to an all-electric vehicle, a plug-in hybrid vehicle, also referred to as a PHEV, or a hybrid vehicle, also referred to as a HEV, where a hybrid vehicle utilizes multiple sources of propulsion including an electric drive system.

Examples herein refer to a vehicle chassis. A vehicle chassis is a framework that bears the load of the rest of the vehicle. A vehicle chassis can include one or more frames, which can be made of steel, aluminum alloy, or another stiff and strong material. For example, a vehicle chassis is sometimes made of at least two side rails connected by multiple cross members for structural integrity. One or more other components, including, but not limited to, a battery pack for an electric or hybrid vehicle, can be integrated into or otherwise combined with a vehicle chassis. A subframe is a chassis portion that can carry certain components, including but not limited to, a motor, drivetrain, or suspension, to spread chassis loads and/or isolate vibrations and harshness.

Examples herein refer to a vehicle body. A vehicle body is the main supporting structure of a vehicle to which components and subcomponents are attached. In vehicles having unibody construction, the vehicle body and the vehicle chassis are integrated into each other. As used herein, a vehicle chassis is described as supporting the vehicle body also when the vehicle body is an integral part of the vehicle chassis. The vehicle body often includes a passenger compartment with room for one or more occupants; one or more trunks or other storage compartments for cargo; and various panels and other closures providing protective and/or decorative cover.

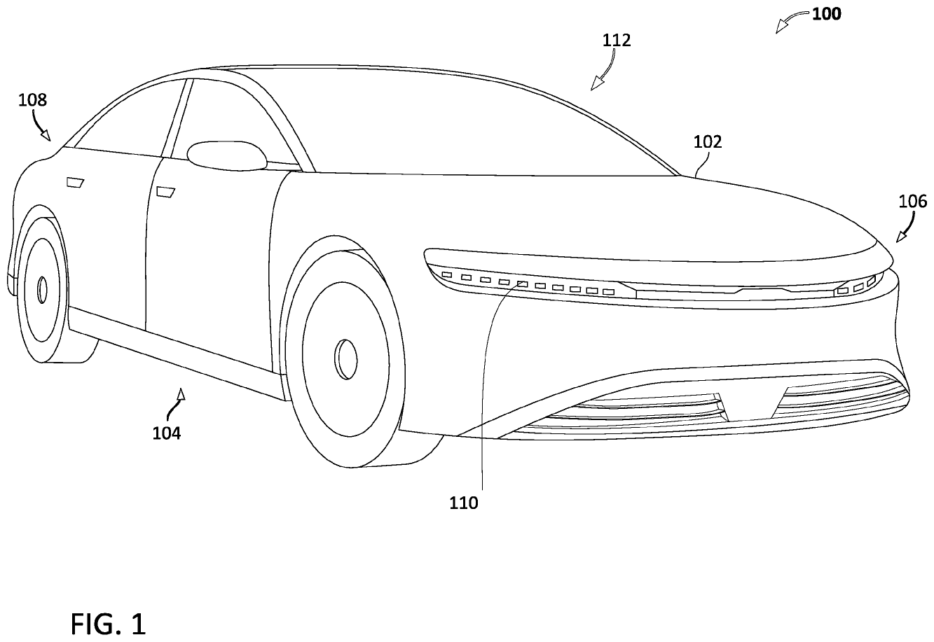

FIG. 1 shows an example of a vehicle 100. The vehicle 100 can be used with one or more other examples described elsewhere herein. The vehicle 100 includes a vehicle body 102 and a vehicle chassis 104 supporting the vehicle body 102. For example, the vehicle body 102 is here of a four-door type with room for at least four occupants, and the vehicle chassis 104 has four wheels. Other numbers of doors, types of vehicle body 102, and/or kinds of vehicle chassis 104 can be used in some implementations.

The vehicle body 102 has a front 106 and a rear 108 and can have a passenger cabin 112 between the front and the rear. The vehicle 100 can have at least one motor, which can be positioned in one or more locations of the vehicle 100. In some implementations, the motor(s) can be mounted generally near the front 106, generally near the rear 108, or both. A battery module can be supported by chassis 104, for example, below the passenger cabin and can be used to power the motor(s). The vehicle 100 can have at least one lighting component, which can be situated in one or more locations of the vehicle 100. For example, the vehicle 100 can have one or more headlights 110 mounted generally near the front 106.

The rear 108 of the vehicle 100 can include a trunk compartment, and the front 106 of the vehicle 100 can include a front trunk (a.k.a., frunk) compartment, each of which is outside the passenger cabin and each of which can be used for storage of vehicle components or personal equipment. For example, one or more electrical circuit modules, for example, as part of a OBC, can be included within the trunk or the frunk can be used to manage the charging of the batteries in the battery module and to manage the distribution of electrical current from the battery module to the one or more motors in the vehicle.

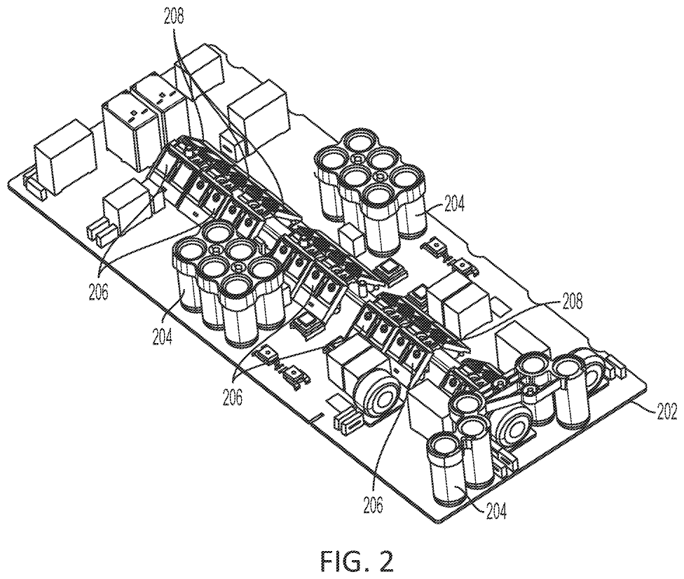

FIG. 2 is a schematic perspective view of a printed circuit board (PCB) 202 for use in an OBC, where a number of electrical components are attached to the PCB. The PCB 202 can be a planar board having a number of electrical traces that are used to make electrical connections between the electrical components. The electrical components can include a plurality of capacitors 204 that extend in a direction perpendicular to the plane of the PCB 202. The electrical components can include a plurality of power chips (e.g., including power SiC MOSFET transistors) 206, 208 that are arranged in two or more rows. For example, a first plurality of first power chips 206 can be arranged in a first row that lies in a first plane, and a second plurality of second power chips 208 can be arranged in a second row that lies in a second plane. In some implementations, the first plane can be oriented at a 90° angle to the second plane. In some implementations, the first plane can be oriented at a 90° angle to the second plane, and both the first plane and the second plane can be oriented at 45° angles relative to the plane of the PCB. Different power chips of the plurality of power chips 206, 208 can be structurally and functionally substantially similar to each other or, different power chips of the plurality of power chips can have different structures and/or functions. The power chips 206, 208 produce heat during their operation.

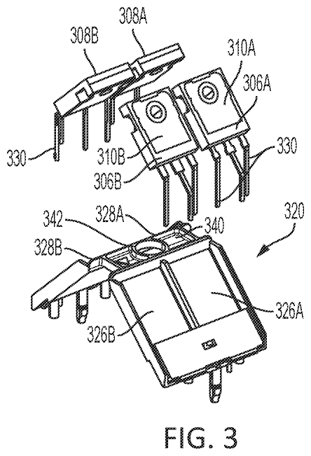

FIG. 3 is a schematic perspective view of four example power chips 306A, 306B, 308A, 308B each of which can include one or more electrical connectors (e.g., metal legs) 330 that can be electrically connected (e.g., soldered) to the printed circuit board 202. For example, power chips 306A, 306B, 308A, 308B, each can include electrical connectors 330 that provide connections to a source, a drain, and a gate of a transistor in the power chip. The power chips 306A, 306B, 308A, 308B each can include, or can be thermally coupled to a heatsink that facilitates the dissipation of heat from a semiconductor material within the power chip away from the chip. For example, heat sinks 310A, 310B are shown as being attached to power chips 306A, 306B, respectively.

A chip holder assembly 320 can be provided to configure the power chips 306A, 306B, 308A, 308B in the two or more planes that are not parallel to each other. For example, the chip holder assembly 320 can include a plurality of receptacles 326A, 326B arranged in a first row in a first plane for receiving a first plurality of power chips 306A, 306B and a second plurality of receptacles 328A, 328B arranged in a second row in a second plane for receiving a second plurality of power chips 328A, 328B.

The chip holder assembly 320 can include a center beam member 340 that connects the receptacles 326A, 326B arranged in the first row in the receptacles 326A, 326B arranged in the second row. The center beam member 340 can include one or more through holes 342 are configured to receive a fastener (e.g., a bolt) that can fasten the chip holder assembly to other components of the OBC, as described herein. The chip holder assembly 320 can be made of an electrically insulating material (e.g., a ceramic material or a polymer material), such that the power chips 306A, 306B, 308A, 308B arranged in the receptacles 326A, 326B, 328A, 328B are electrically isolated from each other.

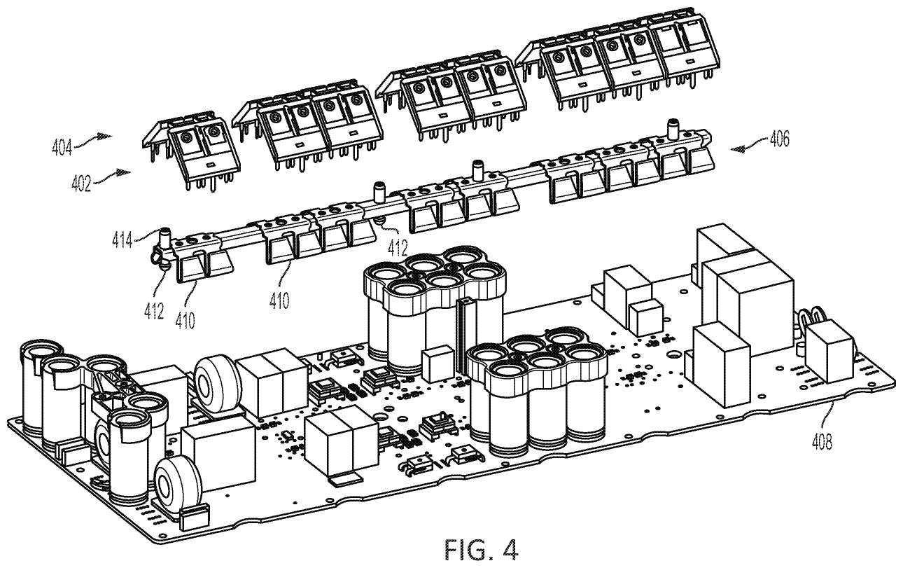

FIG. 4 is an exploded view of a first 402 and second row 404 of power chips, a row 406 of mechanical springs configured to mechanically maintain the power chips in a desired location, and a printed circuit board 408 to which the power chips and the row of springs are fastened when the printed circuit board is used in the OBC.

As shown in FIG. 4, each of the first and second row include 16 power chips, where the first and second rows of power chips are arranged in different planes that are not parallel to each other. For example, the first and second row can be located in first and second planes that are oriented at 90° to each other.

The row 406 of mechanical springs can include a plurality of springs 410 that are configured, in a final assembled state of the OBC, to mechanically couple to undersides of chip holder assemblies in the rows 402, 404 of chips to hold the power chips in good thermal contact with a cooling assembly to extract and dissipate heat from the power chips during operation of the power chips. The springs 410 can be configured and arranged to press against, and apply a force to, the undersides of the chip holder assemblies, such that the heatsinks on the power chips are pressed into good thermal contact with the cooling assembly.

The row 406 of mechanical springs can include one or more fasteners (e.g., bolts) 412, and bushings 414 that can pass through an opening 342 in the chip holder assemblies 320 to fasten the chip holder assemblies, and the power chips received in the chip holder assemblies, to other components of the OBC, as explained in further detail herein.

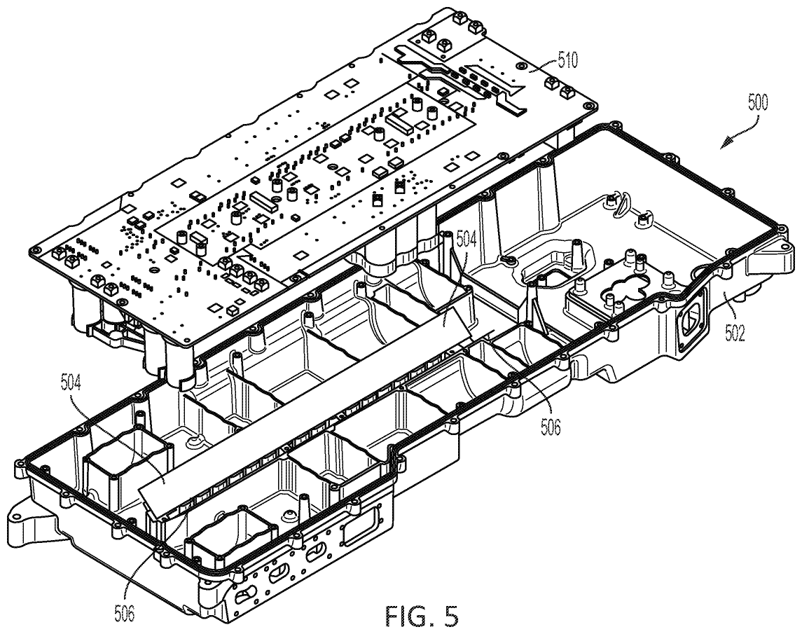

FIG. 5 is a schematic perspective view of one portion 502 of an enclosure 500 in which the rows 402, 404 of power chips can be mounted for use in the OBC. The enclosure 502 also can include one or more cooling channels that are configured to be in thermal contact with the power chips and through which cooling liquid can be circulated to remove heat from the power chips. The portion 502 of the enclosure 500 can include a first surface 504 of a high-thermal-conductivity, electrically insulating material (e.g., a ceramic material) and a second surface 506 of a high-thermal-conductivity, electrically insulating material, where the first and second surfaces are arranged and configured to make good thermal contact with the power chips when the power chips are assembled in the enclosure 500 for use in the OBC. Although the first surface 504 is easily seen in FIG. 5, because of the perspective view of FIG. 5, only the edge of the structure defining the second surface 506 is visible in FIG. 5.

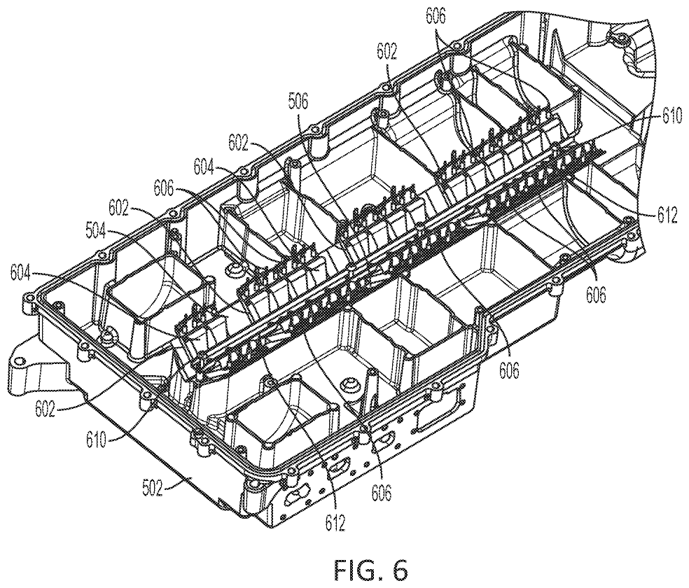

Furthermore, the first and second surfaces 504, 506 are in thermal contact with the cooling channels, so that he can be transferred from the power chips through the surfaces 504, 506, dissipated in the liquid within the cooling channels and ultimately removed from the enclosure 500 when the cooling liquid is circulated out of the enclosure 500. As depicted in FIG. 5, the cooling channels are under the first and second surfaces 504, 506. FIG. 5 does not depict the power chips coupled to the first and second surfaces, which is instead shown in FIG. 6, but rather shows the portion 502 of the enclosure 500 that is configured to receive the power chips. After the power chips are attached to the first and second surfaces 504, 506, the printed circuit board 510 can be lowered into place, such that chip holder assemblies that received the power chips can be mechanically coupled to the printed circuit board and such that electrical connectors 330 of the power chips are positioned on, or relative to, the printed circuit board 510 so that they can be soldered to electrical traces on the printed circuit board 510.

FIG. 6 is a schematic perspective view of a plurality of power chips in a plurality of chip holder assemblies 602 that are coupled to the first and second surfaces 504, 506 of the enclosure 500. Although the power chips themselves are not visible in FIG. 6, the electrical connectors 606 of the power chips that extend through the chip holder assemblies 602 and that are used to make connections to the PCB are depicted in FIG. 6. The chip holder assemblies 602 can be secured to the portion 502 of the enclosure by fasteners (e.g., bolts, screws, etc.) 610 that press a compression beam 612 against the center beam member 340 of the chip holder assemblies 602, which, in turn, presses mechanical springs 604 located between the compression beam 612 and the undersides of the chip holder assemblies 602 (i.e., the sides of the chip holder assemblies distal to the receptacles for the power chips) against the undersides of the chip holder assemblies, such that the power chips received in the assemblies are pressed against the first and second surfaces 504, 506 of the portion 502 of the enclosure. Thermal grease or paste can be applied between the power chips and the first and second surfaces 504, 506 to promote the transfer of heat away from the power chips, through the first and second surfaces to the liquid in the cooling channel.

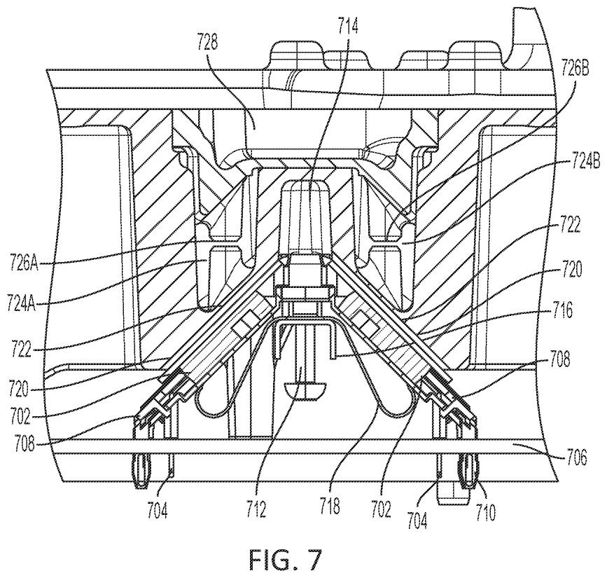

FIG. 7 is a schematic side view of power chips 702 in an assembled position within the enclosure. Electrical contacts 704 of the power chips extend into a printed circuit board 706 and can be soldered to electrical traces on the printed circuit board. The chip holder assembly 708 can receive the power chips 702 in receptacles of the assembly, and mechanical legs 710 of the assembly can be secured to the printed circuit board 706. A fastener 712 can secure the chip holder assembly 708, and thereby the power chips 702, to the portion 502 of the enclosure. For example, when threads of a bolt fastener 712 are secured to threads within a receiving hole 714 of the enclosure, a head of a bolt fastener can press against a bushing that presses a compression beam 716 against a spring 718 such that the spring 718 presses the chip holder assembly 708 (and the power chips within it) against ceramic thermal conductors 720. The ceramic thermal conductors 720 can be in thermal contact with metal (e.g., aluminum) walls 722 of the enclosure, were the metal portions define an inner cavity 724A, 724B through which cooling liquid flows. For example, coolant can enter the cavity through an inlet opening 726A of a cap 728 of the cavity and flow through a first portion of the inner cavity 724A (e.g., into the page shown in FIG. 7) and through a second portion of the inner cavity 724B (e.g., out of the page shown in FIG. 7) and out of an outlet opening 726B in the cap 728. Thus, the flowing cooling liquid can remove heat that is transferred from the cooling chips through the ceramic thermal conductors 720 through metal walls 722 that define the cavity and into the cooling liquid that flows through the cavity.

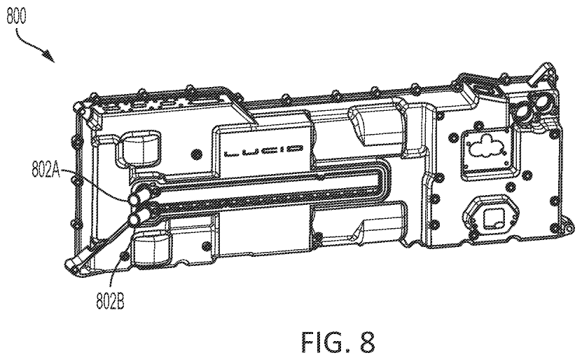

FIG. 8 is a schematic diagram of an enclosure 800 after the power chips have been assembled in their respective plurality of rows that are in different planes and coupled to the cooling channel by forces from the springs and after the power chips have been enclosed within the enclosure, for example, by bolting a first portion of the chamber to a second portion of the enclosure. The enclosure can include an inlet port 802A coupled to the inlet opening 726A to admit cooling liquid into the cooling channel and an outlet port 802B coupled to the outlet opening 726B to receive cooling liquid from the cooling channel.

The terms “substantially” and “about” used throughout this Specification are used to describe and account for small fluctuations, such as due to variations in processing. For example, they can refer to less than or equal to ±5%, such as less than or equal to +2%, such as less than or equal to ±1%, such as less than or equal to ±0.5%, such as less than or equal to ±0.2%, such as less than or equal to ±0.1%, such as less than or equal to ±0.05%. Also, when used herein, an indefinite article such as “a” or “an” means “at least one.”

It should be appreciated that all combinations of the foregoing concepts and additional concepts discussed in greater detail below (provided such concepts are not mutually inconsistent) are contemplated as being part of the inventive subject matter disclosed herein. In particular, all combinations of subject matter appearing in this disclosure are contemplated as being part of the inventive subject matter disclosed herein.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other processes may be provided, or processes may be eliminated, from the described flows, and other components may be added to, or removed from, the described systems.

While certain features of the described implementations have been illustrated as described herein, many modifications, substitutions, changes and equivalents will now occur to those skilled in the art. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

Systems and methods have been described in general terms as an aid to understanding details of the invention. In some instances, well-known structures, materials, and/or operations have not been specifically shown or described in detail to avoid obscuring aspects of the invention. In other instances, specific details have been given in order to provide a thorough understanding of the invention. One skilled in the relevant art will recognize that the invention may be embodied in other specific forms, for example to adapt to a particular system or apparatus or situation or material or component, without departing from the spirit or essential characteristics thereof.

Therefore, the disclosures and descriptions herein are intended to be illustrative, but not limiting, of the scope of the invention.

1. An apparatus comprising:
a plurality of power chips arranged in a first row in a first plane and being electrically coupled to a printed circuit board, the first plane being non-parallel to a plane of the printed circuit board; and
a plurality of power chips arranged in a second row in a second plane and being electrically coupled to the printed circuit board, the second plane being non-parallel to the plane of the printed circuit board and non-parallel to the first plane.

2. The apparatus of claim 1, wherein the first plane is oriented at a 90 degree angle to the second plane.

3. The apparatus of claim 1, wherein the first plane and the second plane are each oriented at 45 degree angles to the plane of the printed circuit board.

4. The apparatus of claim 1, further comprising a chip holder assembly that includes a first row of a first plurality of receptacles configured for receiving the power chips arranged in the first row and second plurality of receptacles configured for receiving the power chips arranged in the second row, the chip holder assembly including a central beam member that connects the first plurality of receptacles to the second plurality of receptacles.

5. The apparatus of claim 4, wherein the central beam member is arranged in a plane parallel to the printed circuit board and includes a plurality of through holes configured for receiving a fastener for securing the chip holder assembly to the printed circuit board.

6. The apparatus of claim 4, wherein the chip holder assembly includes high-thermal-conductivity, electrically insulating ceramic material and where the receptacles are configured for electrically isolating the power chips from each other.

7. The apparatus of claim 1, further comprising a plurality of heat sinks mechanically coupled to the power chips in the first and second rows and configured to extract and dissipate heat from the power chips.

8. The apparatus of claim 1, further comprising a cooling channel in thermal contact with the power chips arranged in the first row and with the power chips arranged in the second row.

9. The apparatus of claim 8, further comprising a plurality of springs configured to press the power chips into thermal contact with the cooling channel.

10. The apparatus of claim 8, further comprising:
a chip holder assembly that includes a first row of a first plurality of receptacles configured for receiving the power chips arranged in the first row and second plurality of receptacles configured for receiving the power chips arranged in the second row, the chip holder assembly including a central beam member that connects the first plurality of receptacles to the second plurality of receptacles; and
a compression beam that is mechanically secured against the central beam member, which, in turn, presses mechanical springs located between the compression beam and the power chips against surfaces of an enclosure surrounding the power chips.

11. The apparatus of claim 8, wherein the cooling channel includes metal walls defining an interior cavity, the apparatus further comprising a plurality of ceramic thermal conductors, the ceramic conductors located between the power chips and a metal wall of the cooling channel and being in thermal contact with the power chip and the metal wall.

12. The apparatus of claim 11, further comprising thermal grease between the ceramic conductors and the power chips.

13. The apparatus of claim 11, wherein the cooling channel includes an inlet configured for injecting coolant liquid into the channel and an outlet configured for the coolant liquid to exit the channel.

14. The apparatus of claim 8, wherein the power chips are located between the cooling channel and the printed circuit board.

15. The apparatus of claim 1, wherein each power chip includes a power SiC MOSFET transistor.

16. The apparatus of claim 1, wherein the power chips are configured to switch electrical power to a battery of an electric vehicle.
